(19) United States
(12) Patent Application Publication
(10) Pub. No.: US 2012/0257334 A1
(43) Pub. Date: Oct. 11, 2012

(54) MOUNTING BRACKET AND ELECTRONIC DEVICE USING THE SAME

(75) Inventors: GUAN-DONG ZHAO, Shenzhen City (CN); XUE-FENG WAN, Shenzhen City (CN); ZHAO-YONG LI, Shenzhen City (CN)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/294,394

(22) Filed: Nov. 11, 2011

(30) Foreign Application Priority Data
Apr. 8, 2011 (CN) 201110088069.0

(51) Int. Cl. H05K 5/00; H05K 7/14

(52) U.S. Cl. 361/679.01; 248/224.8

(57) ABSTRACT

A mounting bracket for mounting a storage mechanism to an electronic device includes a main portion and two fixing portions located at opposite ends of the main portion. At least one of the fixing portions defines a through hole therein, and a buffering protrusion extending out from a surface of the fixing portion and surrounds the through hole. An electronic device having the mounting bracket is also provided.

### BACKGROUND

### Technical Field

The present disclosure relates to mounting brackets, particularly to a mounting bracket for fixing electronic components in an electronic device and an electronic device using the mounting bracket.

In an enclosure of a typical electronic device, there are many kinds of electronic components, such as a CD-ROM drive and a hard disk, mounted on a mounting bracket of the enclosure. Generally, the CD-ROM drive or the hard disk is fixed on the mounting bracket through a plurality of screws. However, the screws will eventually be loosened due to shaking occurred during the transportation, and the CD-ROM drive or hard disk may also be damaged. To overcome the issues due to looseness of the screws, an adhesive is coated on the surface of the screws. However, it will require more time to assemble or disassemble the CD-ROM drive or hard disk.

Therefore, there is room for improvement in the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the mounting bracket and the electronic device. Moreover, in the drawings like reference numerals designate corresponding parts throughout the several views. Wherever possible, the same reference numerals are used throughout the drawings to refer to the same or like elements of an embodiment.

FIG. 1 is an isometric view of a part of an embodiment of an electronic device including a mounting bracket.

FIG. 2 is an exploded, isometric view of the electronic device of FIG. 1.

FIG. 3 is an enlarged, isometric view of the mounting bracket of the electronic device of FIG. 2.

### DETAILED DESCRIPTION

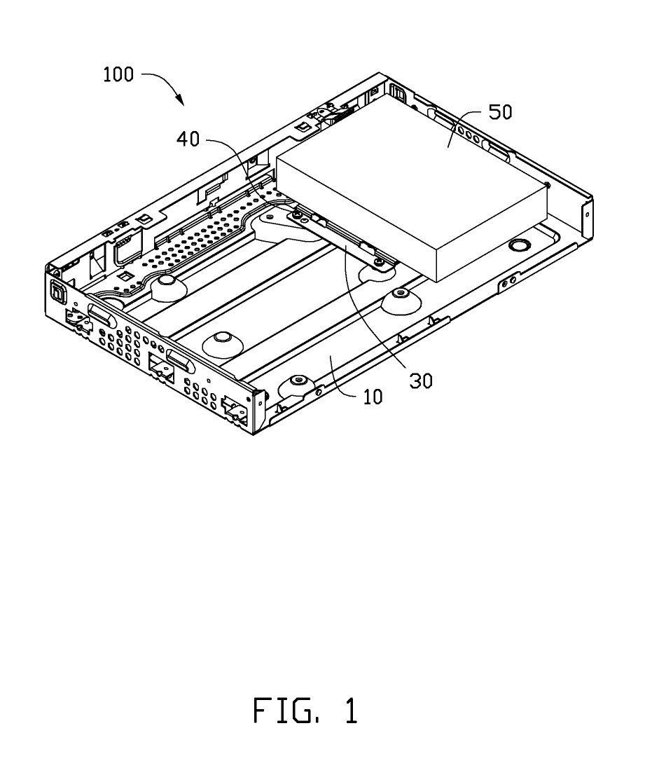

Referring to FIG. 1, an embodiment of an electronic device 100 includes an enclosure 10, a mounting bracket 30 fixed to the enclosure 10, a plurality of fixing members 40, and a storage mechanism 50 fixed to the enclosure 10 via the mounting bracket 30. The electronic device 100 may be a notebook computer, a desktop computer, a liquid crystal display, or other electronic devices. In the illustrated embodiment, the electronic device 100 is a desktop computer.

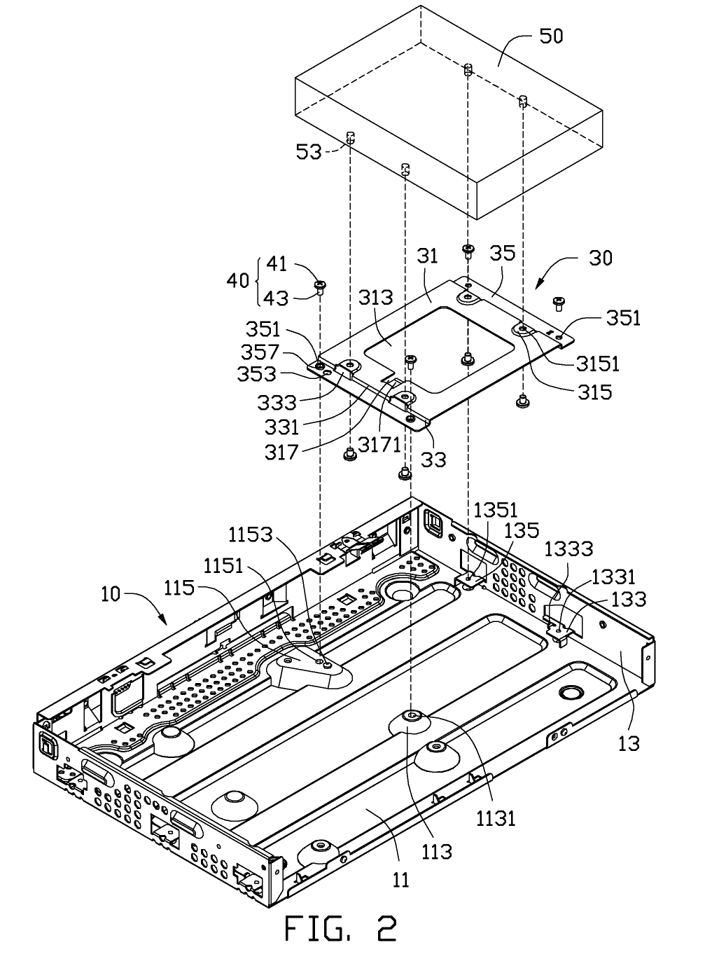

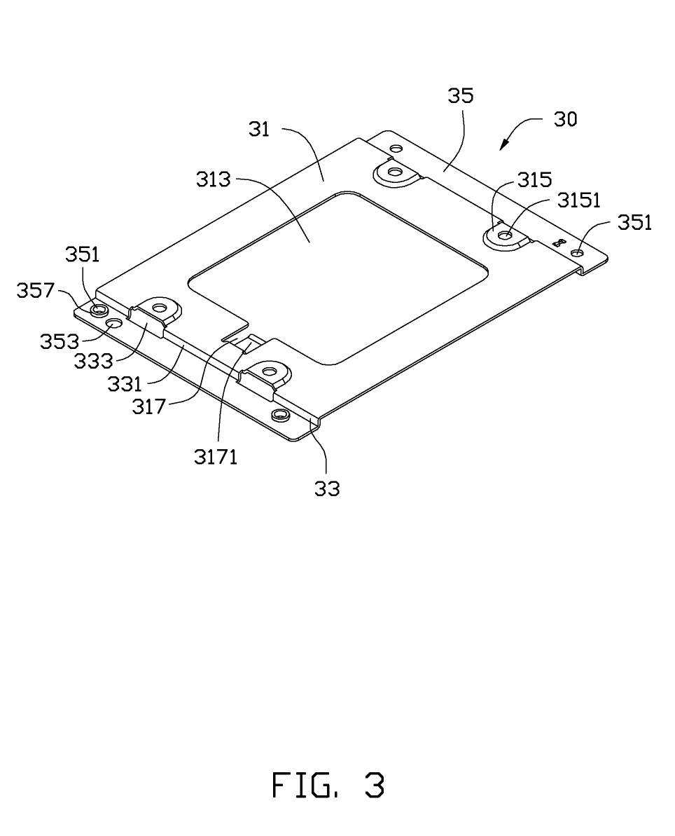

Referring to FIGS. 2 and 3, the enclosure 10 can be a substantially rectangular box. The enclosure 10 includes a base board 11 and a sidewall 13 substantially perpendicularly extending from a side of the base board 11. The base board 11 includes a first fixing portion 113 and a second fixing portion 115 fitted on the base board 11. In the illustrated embodiment, the two fixing portions 113, 115 are arranged in a line parallel to the sidewall 13, and are spaced apart. The first fixing portion 113 can be a substantially conical frustum. The first fixing portion 113 defines a first fixing hole 1131. The second fixing portion 115 can be a substantially triangular frustum. The second fixing portion 115 includes a second fixing hole 1151 defined in a top of the second fixing portion 115 and a convex stage 1153 formed on the top of the second fixing portion 115 adjacent to and apart from the second fixing hole 1151. In the illustrated embodiment, the convex stage 1153 is used to support the storage mechanism 50. The two fixing holes 1131, 1151 are a plurality of screw holes.

The sidewall 13 includes a first mounting portion 133 and a second mounting portion 135 substantially perpendicularly extending from the sidewall 13, respectively. The two mounting portions 133, 135 are arranged apart corresponding to the two fixing portions 113, 115. In the illustrated embodiment, the two mounting portions 133, 135 extend from an inner surface of the sidewall 13 adjacent to the base board 11 towards the fixing portions 113, 115. The fixing portions 113, 115 and the mounting portions 133, 135 are substantially coplanar, and are located at four corners of an imaginary quadrilateral. The first mounting portion 133 includes a protrusion 1333 substantially perpendicularly extending from an end of the first mounting portion 133 adjacent to the second mounting portion 135 to support the mounting bracket 30. The first mounting portion 133 also defines a first mounting hole 1331 at a substantially center of the first mounting portion 133. The second mounting portion 135 defines a second mounting hole 1351 at a substantially center of the second mounting portion 135. The two mounting holes 1331, 1351 are used to fix the mounting bracket 30.

The mounting bracket 30 is a substantially rectangular sheet. The mounting bracket 30 can be detachably fixed to the bottom board 11 of the enclosure 10. The mounting bracket 30 includes a main portion 31, two supporting portions 33, and two fixing portions 35. The two supporting portions 33 extend substantially perpendicularly from opposite ends of the main portion 31 and bend towards the same direction. The mounting bracket 30 further includes two fixing portions 35 substantially perpendicularly extending from the distal ends of the two supporting portions 33, respectively. In the illustrated embodiment, the two fixing portions 35 are parallel to the main portion 31 away from the main portion 31.

The main portion 31 includes an opening 313 for heat dissipation defined in a substantially middle portion of the main portion 31 and two pairs of loading portions 315 located at two opposite ends of the main portion 31 adjacent to the supporting portion 33. Each of the loading portions 315 defines a mounting hole 3151 at approximately the center region of the loading portion 315. The storage mechanism 50 is loaded on the four loading portions 315 to fix to the mounting bracket 30. The main portion 31 further includes a slit 317 defined at an edge of the main portion 31 adjacent to the supporting portion 33 and a latching portion 3171 connected with a sidewall (not labeled) of the slit 317. The slit 317 is communicated with the opening 313. The latching portion 3171 extends out from an inner sidewall of the slit 317, and is bent towards the side of the main portion 31 away from the loading portion 315. The latching portion 3171 is applied to fix the cables (not labeled) to connect the storage mechanism 50 and other components (not shown).

At least one of the supporting portions 33 defines two through holes 333 adjacent to the loading portions 315. In the illustrated embodiment, each of the supporting portions 33 defines the two through holes 333, and each through hole 333 is a narrow elongated hole to enhance the elasticity of the mounting bracket 30 and reduce the shaking and the negative impact on the storage mechanism 50.

The fixing portion 35 can be a substantially sheet. The two fixing portions 35 are used to fix the mounting bracket 30 to the enclosure 10. Each of the fixing portions 35 defines two through holes 351 at opposite ends of the fixing portion 35. One of the fixing portion 35 defines a fixing hole 353 adjacent to one of the through hole 351. Two buffering protrusions 357 extend out from a surface of the fixing portion 35, and surround the corresponding through holes 351. In the illustrated embodiment, the buffering protrusion 357 and the corresponding through holes 351 are coaxial. and are integrally formed. In alternative embodiments, it is not necessary for each through hole 351 to have one corresponding buffering protrusion 357.

The fixing members 40 are used to fix the mounting bracket 30 to the enclosure 10 and fix the storage mechanism 50 to the mounting bracket 30. The fixing member 40 includes a supporting portion 41 at an end of the fixing member 40 and a connecting portion 43 connected to the supporting portion 41. In the illustrated embodiment, the fixing portion 40 is a screw. The number of the fixing member 40 is the same as the total number of the mounting holes 3151 and the through holes 351.

The storage mechanism 50 is fixed to the mounting bracket 30. In the illustrated embodiment, the storage mechanism 50 is a hard disk. In alternative embodiments, the storage mechanism 50 can be a CD-ROM or other components fixed to the electronic device 100 to avoiding shaking. In the illustrated embodiment, the storage mechanism 50 defines four mounting holes 53 at a surface of the storage mechanism 50 adjacent to the mounting bracket 30 corresponding to the mounting hole 3151.

During the assembly of the electronic device 100, the storage mechanism 50 is fixed to the main portion 31 of the mounting bracket 30 via the fixing members 40 passing through the mounting holes 3151 and the mounting holes 53 correspondingly. The mounting bracket 30 together with the storage mechanism 50 are placed on the bottom board 11 of the enclosure 10 to make sure that one fixing portion 35 is resisting with the fixing portions 113, 115, and the other fixing portion 35 is resisting with the mounting portions 133, 135. The mounting bracket 30 is fixed on the enclosure 10 via the fixing members 40 passing through the through holes 351, the fixing holes 1131, 1151, and the mounting holes 1331, 1351. The supporting portion 41 of each fixing member 40 resists with an end of one buffering protrusion 357.

In alternative embodiments, the supporting portion 33 can be omitted as long as the fixing portions 35 extend out from two opposite ends of the main portion 31 directly.

When the storage mechanism 50 is fixed to the enclosure 10 via the mounting bracket 30, the supporting portion 41 of the fixing member 40 resists with an end of the buffering protrusion 357 so as to avoid the supporting portion 41 from resisting with the fixing portion 35. Therefore, it can protect the storage mechanism 50 by avoiding from shaking.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A mounting bracket for mounting a storage mechanism to an electronic device, comprising:
a main portion; and
two fixing portions located at opposite ends of the main portion, wherein at least one of the fixing portions defines a through hole therein, and a buffering protrusion extending out from a surface of the fixing portion and surrounds the through hole.

2. The mounting bracket of claim 1, wherein the buffering protrusion and the through hole are coaxial.

3. The mounting bracket of claim 1, wherein the mounting bracket further comprises two supporting portions extending substantially perpendicularly from opposite ends of the main portion and bending towards the same direction, the two fixing portions extends substantially perpendicularly from a distal end of the supporting portions respectively, and the two fixing portions are both away from and parallel to the main portion.

4. The mounting bracket of claim 3, wherein the main portion comprises an opening for heat dissipation defined in a substantially middle portion of the main portion and two pairs of loading portions located at two opposite ends of the main portion adjacent to the supporting portion, and each of the loading portions defines a mounting hole at the center region of the loading portion.

5. The mounting bracket of claim 3, wherein at least one of the supporting portions defines two through holes adjacent to the two loading portions to enhance the elasticity of the mounting bracket.

6. The mounting bracket of claim 5, wherein the through hole is a narrow elongated hole.

7. The mounting bracket of claim 4, wherein the main portion further comprises a slit defined at an edge of the main portion adjacent to the supporting portion communicating with the opening and a latching portion connected with an inner sidewall of the slit and bent towards the side of the main portion.

8. An electronic device, comprising:
an enclosure;
a mounting bracket fixed to the enclosure, the mounting bracket comprises a main portion and two fixing portions located at opposite ends of the main portion, at least one of the fixing portion defines a through hole, and a buffering protrusion extending out from a surface of the fixing portion and surrounds the through hole;
a storage mechanism fixed to the enclosure via the mounting bracket; and
a fixing member comprising a supporting portion at an end of the fixing member and a connecting portion connected to the supporting portion, wherein the mounting bracket is fixed to the enclosure via the fixing member passing through the through hole with the supporting portion resisting with an end of the buffering protrusion.

9. The mounting bracket of claim 8, wherein the buffering protrusion and the through hole are coaxial.

10. The electronic device of claim 8, wherein the enclosure comprises a base board and a sidewall substantially perpendicularly extending from an end of the base board.

11. The electronic device of claim 10, wherein the base board comprises a first fixing portion and a second fixing portion fitted on the base board, the two fixing portions are arranged in a line parallel to the sidewall, and are spaced apart, and each of the fixing portion defines a fixing hole to fix the mounting bracket to the enclosure via the fixing member passing through the fixing hole.

12. The electronic device of claim 11, wherein the sidewall comprises a first mounting portion and a second mounting portion substantially perpendicularly extending from the sidewall, respectively, the two mounting portion are arranged apart corresponding to the two fixing portions, and each of the mounting portions defines a mounting hole to fix the mounting bracket to the enclosure.

13. The mounting bracket of claim 8, wherein the mounting bracket further comprises two supporting portions extending substantially perpendicularly from opposite ends of the main portion and bending towards the same direction, the two fixing portions extends substantially perpendicularly from a distal end of the supporting portions respectively, and the two fixing portions are both away from and parallel to the main portion.

14. The mounting bracket of claim 13, wherein the main portion comprises an opening for heat dissipation defined in a substantially middle portion of the main portion and two pairs of loading portions located at two opposite ends of the main portion adjacent to the supporting portion, and each of the loading portions defines a mounting hole at the center region of the loading portion.

15. The mounting bracket of claim 13, wherein at least one of the supporting portions defines two through holes adjacent to the two loading portions to enhance the elasticity of the mounting bracket.

16. The mounting bracket of claim 15, wherein the through hole is a narrow elongated hole.

17. The mounting bracket of claim 14, wherein the main portion further comprises a slit defined at an edge of the main portion adjacent to the supporting portion communicating with the opening and a latching portion connected with an inner sidewall of the slit and bent towards the side of the main portion.
